(19) United States
(12) Patent Application Publication
(10) Pub. No.: US 2026/0198378 A1
(43) Pub. Date: Jul. 9, 2026

(54) PASSIVE COMPONENT MODULE AND SEMICONDUCTOR PACKAGE INCLUDING THE SAME

(71) Applicant: SAMSUNG ELECTRONICS CO., LTD., Suwon-si (KR)

(72) Inventors: Kyojin HWANG, Suwon-si (KR); Sunghawn BAE, Suwon-si (KR)

(73) Assignee: SAMSUNG ELECTRONICS CO., LTD., Suwon-si (KR)

(21) Appl. No.: 19/262,910

(22) Filed: Jul. 8, 2025

(30) Foreign Application Priority Data
Jan. 8, 2025 (KR) 10-2025-0003090

(51) Int. Cl. H01L 25/16; H01L 21/48; H01L 21/683; H01L 23/00; H01L 23/13; H01L 23/528; H01L 23/538; H01L 23/64

(52) U.S. Cl. CPC H10W 90/00; H10W 20/427; H10W 44/601; H10W 70/611; H10W 70/65; H10W 70/68; H10W 90/401; H10P 72/74; H10W 70/093; H10W 74/15; H10W 90/724; H10W 90/734

(57) ABSTRACT

A passive component module includes a support substrate, a plurality of passive components stacked on the support substrate in a first direction, each passive component including a body having a first surface and a second surface facing each other in the first direction, and a first electrode and a second electrode spaced apart on the first surface of the body, and a plurality of adhesive members between the support substrate and the plurality of passive components and between the plurality of passive components, respectively.

### CROSS-REFERENCE TO RELATED APPLICATION

This application claims priority to Korean Patent Application No. 10-2025-0003090, filed on Jan. 8, 2025, in the Korean Intellectual Property Office, the disclosure of which is incorporated by reference herein in its entirety.

### BACKGROUND

### 1. Field

The present disclosure relates to a passive component module and a semiconductor package including the same.

### 2. Description of Related Art

With the development of artificial intelligence (AI) and autonomous driving technology, product requirements are rapidly increasing, and accordingly, the size of semiconductor packages required in systems is increasing. Examples of the large-area packages include 2.5D packages using silicon interposers and 2.3D packages using bridge chips.

One of the methods for improving the characteristics of large-area packages is to introduce multilayer ceramic capacitors (MLCCs), silicon capacitors, or the like, into the package to improve power characteristics. These capacitors are advantageous when designed to be close to the semiconductor chip. Embedded capacitors have an advantage in power transfer efficiency compared to die-side capacitors (DSCs) and land-side capacitors (LSCs).

### SUMMARY

One or more embodiments provide a passive component module and a semiconductor package including the same, which can be embedded in a thick core substrate.

Further, one or more embodiments provide a passive component module and a semiconductor package including the same, capable of securing high capacitance.

Further still, one or more embodiments provide a passive component module and a semiconductor package including the same, capable of being vertically connected.

According to an aspect of the disclosure, a passive component module may include: a support substrate; a plurality of passive components stacked on the support substrate in a first direction, each of the plurality of passive components including: a body having a first surface and a second surface facing the first surface in the first direction, a first electrode on the first surface of the body, and a second electrode disposed on the first surface of the body and spaced apart from the first electrode; and a plurality of adhesive members between the support substrate and the plurality of passive components and between the plurality of passive components.

According to an aspect of the disclosure, a semiconductor package may include: a component embedded substrate; and at least one semiconductor chip on the component embedded substrate and electrically connected to the component embedded substrate, wherein the component embedded substrate includes: a first redistribution structure; a core substrate on the first redistribution structure and electrically connected to the first redistribution structure, the core substrate having a first through-hole therein; a passive component module on the first redistribution structure, at least a portion of the passive component module being disposed within the first through-hole and electrically connected to the first redistribution structure, the passive component module including a plurality of passive components arranged along a first direction; an encapsulant filling at least a portion of the first through-hole, and covering at least a portion of the passive component module; and a second redistribution structure extending on the core substrate and the passive component module, and electrically connected to the core substrate and the passive component module, wherein the first direction intersects a second direction in which the first through-hole penetrates the core substrate, and each of the plurality of passive components includes: a first electrode connected to the second redistribution structure; and a second electrode spaced apart from the first electrode in the second direction and connected to the first redistribution structure.

According to an aspect of the disclosure, a semiconductor package may include: a first semiconductor package; a second semiconductor package on the first semiconductor package; a plurality of conductive bumps between the first semiconductor package and the second semiconductor package; and a passive component module disposed adjacent the plurality of conductive bumps between the first semiconductor package and the second semiconductor package, the passive component module including a plurality of passive components arranged along a first direction, wherein the first direction intersects a second direction from the first semiconductor package toward the second semiconductor package, wherein each of the plurality of passive components includes: a first electrode connected to the second semiconductor package; and a second electrode spaced apart from the first electrode in the second direction and connected to the first semiconductor package.

According to an aspect of the disclosure, a method of manufacturing a passive component module may include stacking a plurality of passive components each including a body, and a first electrode and a second electrode disposed spaced apart on a first surface of the body on a support substrate.

According to an aspect of the disclosure, a method of manufacturing a semiconductor package may include manufacturing a component embedded substrate, and disposing at least one semiconductor package on the component embedded substrate, where the manufacturing of the component embedded substrate may include disposing a passive component module including a plurality of passive components arranged along a first direction within a through-hole of a core substrate, forming an encapsulant that fills at least a portion of the through-hole and covers at least a portion of the passive component module, forming a second redistribution structure on a first surface of the core substrate, and forming a first redistribution structure on a second surface of the core substrate, and where the first direction intersects a second direction in which the through-hole penetrates the core substrate.

According to an aspect of the present disclosure, a passive component module and a semiconductor package including the same, which can be embedded in a thick core substrate, may be provided.

According to an aspect of the present disclosure, a passive component module and a semiconductor package including the same, capable of securing high capacitance, may be provided.

According to an aspect of the present disclosure, a passive component module and a semiconductor package including the same, capable of being vertically connected, may be provided.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a cross-sectional view of a passive component module according to an embodiment;

FIG. 2 is a cross-sectional view of taken along line I-I′ of the passive component module of FIG. 1;

FIG. 3 is a cross-sectional view of a passive component module according to an embodiment;

FIG. 4 is a cross-sectional view of a passive component module according to still an embodiment;

FIG. 5 is a cross-sectional view of a semiconductor package according to an embodiment;

FIG. 6 and FIG. 7 illustrate an example electrical connection configuration of electrodes of a passive component module in the semiconductor package of FIG. 5;

FIGS. 8 and 9 illustrate another example electrical connection configuration of electrodes of a passive component module in the semiconductor package of FIG. 5;

FIG. 10 is a cross-sectional view of a semiconductor package according to an embodiment;

FIG. 11 is a cross-sectional view of a semiconductor package according to still an embodiment;

FIG. 12 is a cross-sectional view of a semiconductor package according to still an embodiment;

FIG. 13 is a cross-sectional view of a semiconductor package according to still an embodiment;

FIG. 14 is a cross-sectional view of a semiconductor package according to still an embodiment;

FIGS. 15 to 18 are manufacturing process diagrams of a passive component module according to an embodiment;

FIGS. 19 to 29 are manufacturing process diagrams of a semiconductor package according to an embodiment.

### DETAILED DESCRIPTION

Example embodiments of the present disclosure will be described more fully hereinafter with reference to the accompanying drawings. As those skilled in the art will realize, the described embodiments may be modified in various different ways, without departing from the spirit or scope of the present disclosure.

The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. For better understanding and ease of description, the thickness of some layers and areas is exaggerated.

Throughout this specification and the claims that follow, when it is described that an element is “coupled” or “connected” to another element, the element may be “directly coupled” or “directly connected” to the other element or “indirectly coupled” or “indirectly connected” to the other element through a third element. In a similar sense, this includes being “physically connected” as well as being “electrically connected”.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, sequential numbers such as first and second are used to distinguish a certain component from another component that is the same or similar to the certain component, and are not necessarily intended to refer to a specific component. Accordingly, a component referred to as a first component in a particular portion of the specification may be referred to as a second component in another portion of the specification.

In addition, throughout the specification, a singular reference to a component includes references to a plurality of these components, unless specifically stated to the contrary.

In addition, throughout the specification, references to one (or first) surface and the other (or second) surface are intended to distinguish different surfaces from each other, and are not necessarily intended to limit it to a specific surface. Therefore, a surface referred to as one (or first) surface in a specific portion of the specification may be referred to as the other (or second) surface in another portion of the specification.

Furthermore, throughout the specification, references to directions such as upper surface, upper side, upper portion, lower surface, lower side, and lower portion are described based on the drawings to facilitate explanation and understanding.

Hereinafter, a passive component module and a semiconductor package including the same according to embodiments of the present disclosure will be described with reference to the drawings.

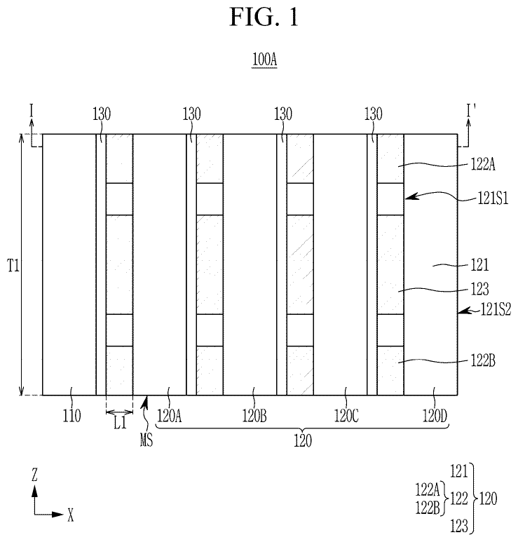

FIG. 1 is a cross-sectional view of the passive component module according to an embodiment.

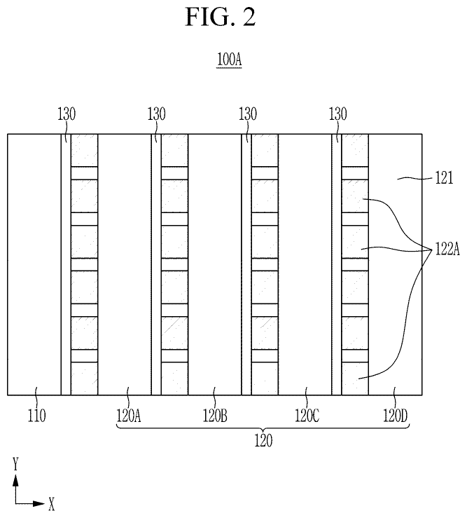

FIG. 2 is a cross-sectional view of taken along line I-I′ of the passive component module of FIG. 1.

A passive component module 100A according to an embodiment may include a support substrate 110, a plurality of passive components 120 arranged on the support substrate 110 along an X-direction, and a plurality of adhesive members 130 disposed between the support substrate 110 and the plurality of passive components 120 and between the plurality of passive components 120.

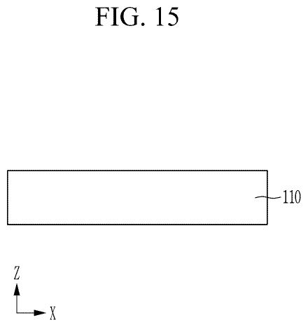

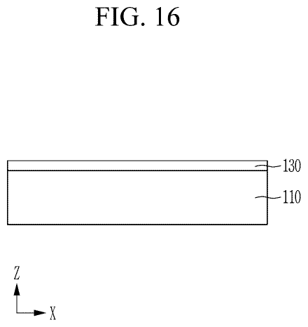

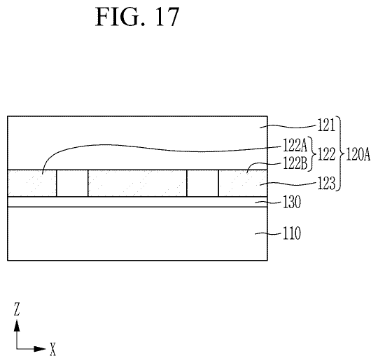

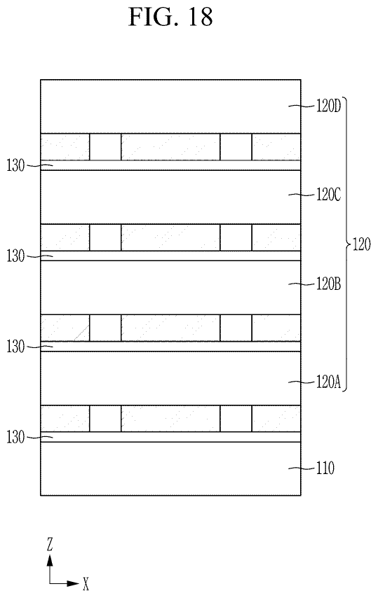

The passive component module 100A according to an embodiment may be manufactured by stacking the passive components 120 on a first surface of the support substrate 110 (see FIG. 15 to FIG. 18), and may be used by rotating such that the surface on which a second electrode 122B is disposed may become a mounting surface MS. Depending on directions in which the passive component module 100A is viewed, the passive components 120 may be understood to be stacked on the support substrate 110. From this viewpoint, in some part(s) of the present disclosure, the passive components 120 may be described to be stacked on the support substrate 110 in the X-direction (i.e., side-stacked).

The support substrate 110 may be a base structure for stacking the passive components 120. In addition, the support substrate 110 may serve to protect the passive component 120 adjacent to the support substrate 110, for example, the electrode 122 of the passive component 120.

The support substrate 110 may be a dummy wafer or may be manufactured by processing (e.g., cutting) a dummy wafer. For example, the support substrate 110 may be a semiconductor substrate of silicon (Si), germanium (Ge), or the like or a compound semiconductor substrate of gallium arsenide (GaAs), silicon carbide (SiC), or the like. However, the support substrate 110 may be another type of substrate, such as an organic substrate or a glass substrate.

The support substrate 110 may have a first surface and a second surface facing each other in the X-direction, and the passive components 120 may be stacked on the first surface of the support substrate 110. A length of the support substrate 110 along the X-direction may correspond to a thickness of a dummy wafer. The length of the support substrate 110 along the X-direction may be, for example, 500 μm to 1000 μm, 600 μm μm to 900 μm, 700 μm to 800 μm, or about 780 μm. The support substrate 110 may have a generally rectangular plate shape, but a shape of the support substrate 110 is not limited thereto.

When manufacturing the passive component module 100A, the passive components 120 in the wafer state may be bonded on the support substrate 110 of the wafer state in the wafer-on-wafer (WoW) method. Individual passive component modules 100A may be manufactured by cutting a structure in which the support substrate 110 in the wafer state and the passive components 120 in the wafer state are wafer-on-wafer bonded. By the cutting, a length of the support substrate 110 along a Z-direction and a Y-direction (i.e., a length formed by cutting surfaces) may be the same as a length of the passive component 120 along the Z-direction and the Y-direction, respectively. However, the passive components 120 may be bonded on the support substrate 110 in another method such as chip-on-wafer (CoW) or chip-on-chip (CoC).

The passive components 120 may be arranged on the support substrate 110 along the X-direction. For example, the passive components 120 may include a first passive component 120A, a second passive component 120B, a third passive component 120C and a fourth passive component 120D, which are sequentially arranged on the first surface of the support substrate 110 along the X-direction.

Each passive component 120 may be a passive component of a chip type. For example, the passive component 120 may be a silicon capacitor. However, the type of the passive component 120 may be changed in implementation.

Each passive component 120 may include a body 121 and the electrodes 122.

The body 121 may have a first surface 121S1 and a second surface 121S2 facing each other in the X-direction.

The body 121 may be one formed based on a wafer. The body 121 may include, for example, a semiconductor such as silicon (Si) or germanium (Ge) or a compound semiconductor such as gallium arsenide (GaAs) or silicon carbide (SiC). Trenches for securing high capacitance may be formed in an interior of the body 121. However, depending on the type of the passive component 120, the body 121 may include an organic material or an inorganic material such as ceramic.

The electrodes 122 may be disposed on the first surface 121S1 of the body 121. For example, the electrodes 122 may include a first electrode 122A and a second electrode 122B spaced apart from each other on the first surface 121S1 of the body 121. The electrodes 122 may disposed on the first surface 121S1 of the body 121 such that at least a portion of each protrudes. The electrodes 122 may not exist on the second surface 121S2 and a side surface (a surface connecting the first surface 121S1 and the second surface 121S2) of the body 121.

A length L1 of the electrode 122 in the X-direction may be 50 μm or more, 50 μm to 150 μm, or 50 μm to 100 μm. When the length L1 of the electrode 122 in the X-direction is less than 50 μm, stable connection to other components vertically connected to the electrode 122 may be difficult. When the length L1 of the electrode 122 in the X-direction exceeds 150 μm, the size of the passive component module 100A may excessively increase.

The second electrode 122B may be disposed on a lower surface, which is the mounting surface MS of the passive component module 100A, and the first electrode 122A may be disposed on an upper surface, which is an opposite surface of the mounting surface MS of the passive component module 100A (see FIG. 1). The mounting surface MS of the passive component module 100A may be a surface of the passive component module 100A disposed on another component. The first electrode 122A and the second electrode 122B may be spaced apart in the Z-direction. At least a portion of each of the first electrode 122A and the second electrode 122B may overlap in the Z-direction. The second electrode 122B may be electrically connected to another component on which the passive component module 100A is disposed, and the first electrode 122A may be electrically connected to still another component disposed on the passive component module 100A.

The second electrode 122B may be exposed through a lower surface, which is the mounting surface MS of the passive component module 100A, and the first electrode 122A may be exposed through an upper surface of the passive component module 100A (see FIG. 1). For example, on the mounting surface MS of the passive component module 100A, a lower surface of the second electrode 122B may be coplanar with a lower surface of the support substrate 110 and/or a lower surface of the body 121, and on the opposite surface of the mounting surface MS, an upper surface of the first electrode 122A may be coplanar with an upper surface of the support substrate 110 and/or an upper surface of the body 121. As the first electrode 122A and the second electrode 122B are exposed through the upper surface and the lower surface of the passive component module 100A, respectively, easy connection to other components may be provided.

In each passive component 120, a plurality of second electrodes 122B and a plurality of first electrodes 122A may be provided. For example, referring to FIG. 2, each passive component 120 may include a plurality of first electrodes 122A arranged along the Y-direction and a plurality of second electrodes 122B arranged along the Y-direction. The number of the second electrodes 122B and the first electrodes 122A included in each passive component 120 is not particularly limited, and may be changed depending on the implementations.

A conductive material may be used as a material of the electrode 122. For example, the electrode 122 may include at least one among doped silicon, metal (e.g., copper (Cu), aluminum (Al), gold (Au), silver (Ag), platinum (Pt), nickel (Ni), tin (Sn), and/or lead (Pb)), and an alloy of metals (e.g., a solder of Sn-Ag alloy, Sn-Ag-Cu alloy, or the like).

If necessary, the electrode 122 may be configured in a plurality of layers For example, the electrode 122 may be manufactured by forming a first layer including polysilicon on the first surface 121S1 of the body 121, and forming a second layer including copper (Cu) on the first layer. The second layer may be formed in an appropriate size to provide stable connection to another component.

Each passive component 120 may be disposed so that the first surface 121S1 of the body 121 on which the electrodes 122 is disposed may face the support substrate 110. However, some or all of the passive components 120 may be disposed so that the second surface 121S2 may face the support substrate 110.

In an embodiment, each passive component 120 may further include a dummy electrode 123 disposed on the first surface 121S1 of the body 121. The dummy electrode 123 may help prevent a crack caused by the stack of the passive components 120. The dummy electrode 123 may be disposed, for example, between the first electrode 122A and the second electrode 122B. The dummy electrode 123 may be spaced apart from the first electrode 122A and the second electrode 122B. The dummy electrode may be formed of a same material as a material of the electrode 122, but another material may be used. The dummy electrode 123 may be have a size greater than sizes of the first electrode 122A and the second electrode 122B, but is not limited thereto. The number of the dummy electrode(s) 123 and the interval with respect to the electrode 122 may not be particularly limited either, and may be changed depending on implementations.

The adhesive members 130 may be disposed between and attach the support substrate 110 and the passive component 120 (120A) and between the passive components 120. For example, the adhesive member 130 may be disposed between the support substrate 110 and the electrode 122 of the passive component 120A and between the body 121 of the passive component 120 (120A) and the electrode 122 of another passive component 120 (120B).

The adhesive member 130 may be introduced when wafer-on-wafer bonding the support substrate 110 in the wafer state and the passive components 120 in the wafer state, and may be cut at the same time when cutting a structure in which the support substrate 110 in the wafer state and the passive components 120 in the wafer state are wafer-on-wafer bonded. By the cutting, a length of the adhesive member 130 along the Z-direction and the Y-direction may be the same as the lengths of the support substrate 110 and the passive component 120 along the Z-direction and the Y-direction, respectively.

The adhesive member 130 may be formed of a material having an insulating property and adherence, and may be, for example, a non-conductive adhesive film. The non-conductive adhesive film may provide excellent properties in terms of heat dissipation, high reliability, and process efficiency.

A thickness T 1 of the passive component module 100A may be 1 mm or more. In the present disclosure, “thickness” of the passive component module 100A may mean a length in the Z-direction from the second electrode 122B toward the first electrode 122A. According to one or more embodiments of the present disclosure, by side-stacking the passive components 120, the passive component module 100A having a thick thickness without limitation caused by the wafer thickness may be manufactured. In addition, the passive component module 100A capable of securing high capacitance by stacking the plurality of passive components 120 may be provided. In addition, since vertical connection to the mounting surface MS may be enabled through the first electrode 122A and the second electrode 122B located on the opposite surface, respectively, the passive component module 100A having characteristics advantageous for a power distribution network (PDN) may be provided.

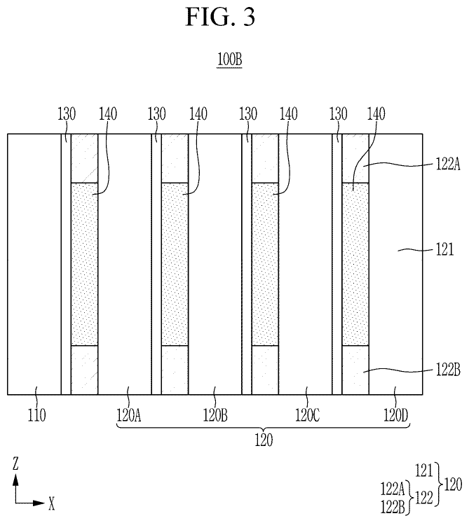

FIG. 3 is a cross-sectional view of the passive component module according to an embodiment.

In an embodiment, a passive component module 100B may further include a filler 140 filling at least a portion of a space between the electrodes 122. The filler 140 may help prevent a crack due to the stack of the passive components 120, similarly to the dummy electrode 123. The filler 140 may fill, for example, at least a portion of a space between the first electrode 122A and the second electrode 122B. The filler 140 may be in contact with the electrodes 122. For example, the filler 140 may cover at least a portion of a side surface of the electrode 122. The filler 140 may include an insulative material such as an epoxy molding compound (EMC), polyimide (PI), epoxy, Ajinomoto Build-up Film (ABF), prepreg (PPG). The filler 140 may be formed by compression molding, transfer molding, or the like.

In an embodiment, the passive component module 100B may include the dummy electrode 123 together with the filler 140, and in this case, the filler 140 may fill at least a portion of a space between the electrode 122 and the dummy electrode 123.

For configurations other than the above, the content described in detail in other portions of the present disclosure may be equally applied, unless particularly contradictory.

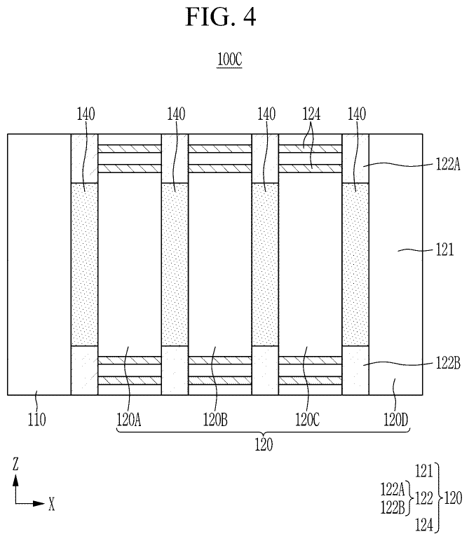

FIG. 4 is a cross-sectional view of the passive component module according to still an embodiment.

At least one among the passive components 120 of a passive component module 100C may further include penetration electrodes 124 for connection between the electrodes 122. For example, the first passive component 120A, the second passive component 120B, the third passive component 120C may include the penetration electrode 124. The fourth passive component 120D disposed outermost among the passive components 120 may not include the penetration electrode 124.

Each penetration electrode 124 may penetrate at least a portion of the body 121 in the X-direction. In addition, the penetration electrode 124 may electrically connect the electrode 122 of a first one passive component 120 and the electrode 122 of a second one passive component 120. Some of the penetration electrodes 124 may electrically connect the first electrodes 122A of the passive component 120, and others thereof may electrically connect the second electrodes 122B of the passive component 120.

A conductive material may be used as a material of the penetration electrode 124. For example, a metal or an alloy of metals such as copper (Cu), aluminum (Al), or tungsten (W) may be used as a material of the penetration electrode 124. In an embodiment, an insulative barrier layer may be additionally interposed between the penetration electrode 124 and the body 121.

The adhesive member 130 disposed between the passive components 120 for connection between the penetration electrode 124 and the electrode 122 may be omitted, and the passive components 120 may be directly bonded. The adhesive member 130 disposed between the support substrate 110 and the passive component 120A may be omitted, or may exist.

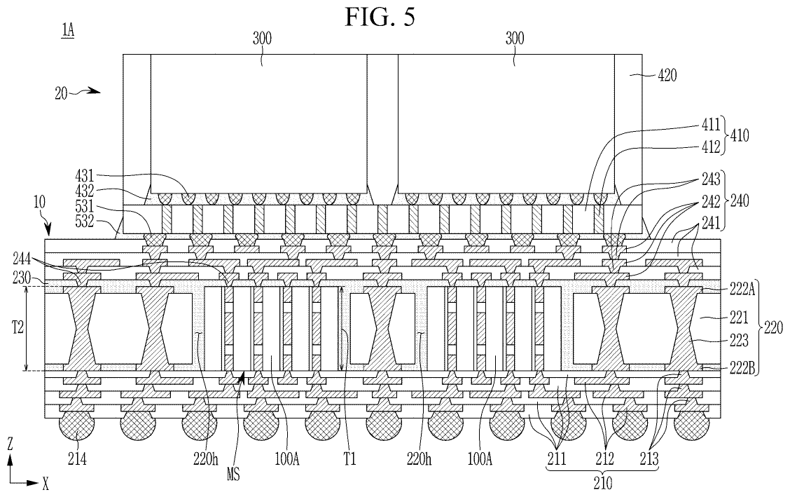

FIG. 5 is a cross-sectional view of the semiconductor package according to an embodiment.

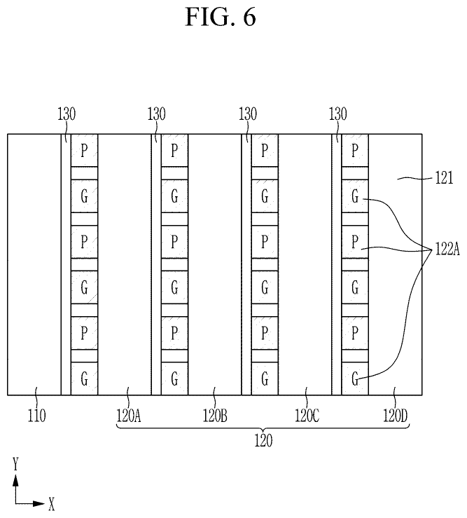

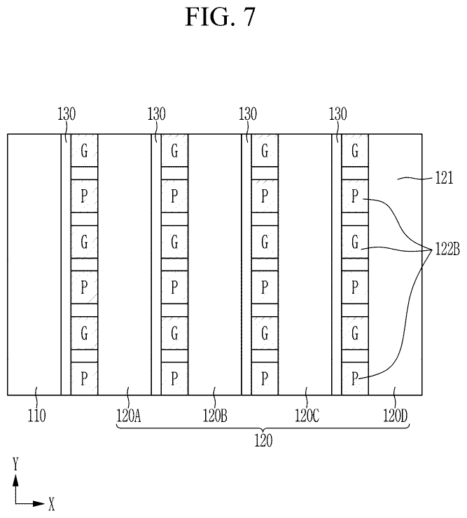

FIGS. 6 and 7 illustrate an example electrical connection configuration of the electrodes of the passive component module in the semiconductor package of FIG. 5.

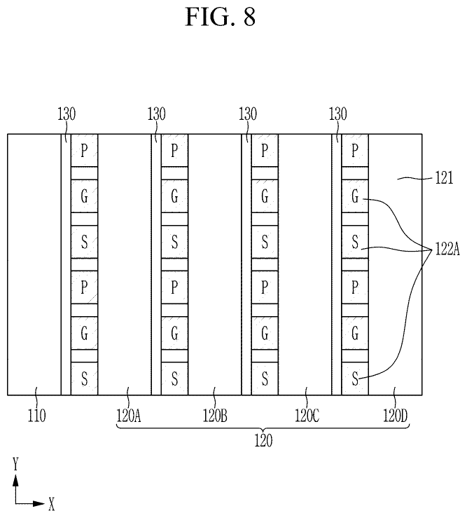

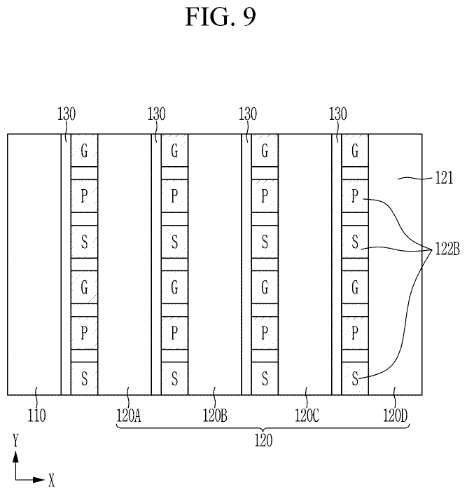

FIGS. 8 and 9 illustrate another example electrical connection configuration of the electrodes of the passive component module in the semiconductor package of FIG. 5.

FIGS. 6 to 9 illustrate a planal arrangement of components of the passive component module.

The passive component module 100A may be applied to a large-area 2.5D semiconductor package including an interposer substrate 410 providing electrical connection between semiconductor chips 300.

Referring to FIG. 5, a semiconductor package 1A according to an embodiment may include a component embedded substrate 10 including the passive component module 100A, and an upper semiconductor package 20 disposed on the component embedded substrate 10 and including a plurality of semiconductor chips 300.

The component embedded substrate 10 may include, for example, a first redistribution structure 210, a core substrate 220 disposed on the first redistribution structure 210 and having a through-hole 220h, the passive component module 100A disposed on the first redistribution structure 210 so that at least a portion may be disposed within the through-hole 220h, an encapsulant 230 filling at least a portion of the through-hole 220h and covering at least a portion of the passive component module 100A, and a second redistribution structure 240 extending on the core substrate 220 and the passive component module 100A.

The first redistribution structure 210 may include first redistribution insulation layers 211, first redistribution wiring layers 212, and first redistribution vias 213.

The first redistribution insulation layer 211 may cover the first redistribution wiring layer 212, and may prevent an electrical short between the first redistribution wiring layers 212. An insulative material such as a photo-imageable dielectric (PID) may be used as a material of the first redistribution insulation layer 211. When a photo-imageable dielectric is used as a material of the first redistribution insulation layer 211, it may be advantageous for implementation of fine pitches. The first redistribution insulation layer 211 disposed lowermost among the first redistribution insulation layers 211 may serve as a passivation layer.

The first redistribution wiring layers 212 may be respectively disposed on the first redistribution insulation layer 211. The first redistribution wiring layers 212 may include wires such as a signal wire for signal transmission, a power wire for supplying power, and a ground wire for grounding. A conductive material such as copper (Cu) or aluminum (Al) may be used as a material of the first redistribution wiring layer 212.

The first redistribution vias 213 may connect the first redistribution wiring layers 212 buried in the first redistribution insulation layer 211 and located in different layers. A conductive material may be used as a material of the first redistribution via 213, the same as the first redistribution wiring layer 212. The first redistribution via 213 may have various shapes such as a cylindrical shape or a tapered shape.

Conductive bumps 214 may be disposed on a lower surface of the first redistribution structure 210. The conductive bumps 214 may be electrically connected to the first redistribution structure 210, and may electrically connect the semiconductor package 1A to another component such as a main substrate. A conductive material such as a solder may be used as a material of the conductive bump 214. The size, shape, spacing, or the like of the conductive bumps 214 is not particularly limited, and may be changed depending on the implementations.

The core substrate 220 may be disposed on the first redistribution structure 210 and electrically connected to the first redistribution structure 210. The core substrate 220 may be directly disposed on the first redistribution structure 210, but is not limited thereto.

The core substrate 220 may have at least one through-hole 220h in which the passive component module 100A is disposed. The number of the through-hole 220h is not particularly limited, and may be changed according to the number of the passive component module 100A or the like. In each through-hole 220h, a single passive component module 100A may be disposed, and a plurality of passive component modules 100A may be disposed. The through-hole 220h may be formed by laser processing, mechanical processing, or the like. Depending on the processing method, a width of the through-hole 220h on the cross-section may be constant, or may be narrowed in a direction from a first side toward a second side.

The core substrate 220 may include a core insulation layer 221, a first wiring layer 222A and a second wiring layer 222B disposed on both surfaces of the core insulation layer 221, respectively, a through via 223 penetrating the core insulation layer 221 and electrically connecting the first wiring layer 222A and the second wiring layer 222B.

The core substrate 220 may have a thick thickness for warpage control. For example, a thickness T2 of the core substrate 220 in the Z-direction may be 1 mm or more.

In order to provide a core substrate 220 having a thick thickness, the core insulation layer 221 may also have a thick thickness. An insulative material such as prepreg, Ajinomoto Build-up Film (ABF), polyimide (PI), or epoxy may be used as a material of the core insulation layer 221. In order to provide the core substrate 220 having excellent rigidity for warpage control, the core substrate 220 may further include a filler such as glass fiber, carbon fiber, silica, or alumina.

The first wiring layer 222A and the second wiring layer 222B may be disposed on the both surfaces of the core insulation layer 221 in a protruding form, respectively. Depending on the manufacturing method, at least one among the first wiring layer and the second wiring layer 222B may be disposed in the form partially embedded into the core insulation layer 221. The first wiring layer 222A and the second wiring layer 222B may also configure wires such as a signal wire for signal transmission, a power wire for supplying power, and a ground wire for grounding. A conductive material such as copper (Cu) or aluminum (Al) may be used as a material of each of the first wiring layer 222A and the second wiring layer 222B.

The same as the first wiring layer 222A and the second wiring layer 222B, a conductive material may be used as a material of the through via 223. The through via 223 may have various shapes such as an hourglass shape, a cylindrical shape, or a tapered shape.

The passive component module included into the semiconductor package 1A may be one of the passive component modules 100A and 100B according to an embodiment of the present disclosure, and in the present disclosure, may be illustrated and described to be the passive component module 100A merely as an example. The passive component module 100A may be included the semiconductor package 1A as a single component.

The passive component module 100A may be disposed on the first redistribution structure 210 so that at least a portion may be disposed within the through-hole 220h and electrically connected to the first redistribution structure 210. The passive component module 100A may be spaced apart from the core substrate 220, and at least a portion of the space each between the passive component module 100A and the core substrate 220 may be filled with the encapsulant 230. The passive component module 100A may be directly disposed on the first redistribution structure 210, but is not limited thereto.

The passive component module 100A may be disposed on the first redistribution structure 21 (in the same direction as illustrated in FIG. 1) so that the surface on which the second electrode 122B is disposed may become the mounting surface MS. Therefore, the direction in which the plurality of passive components 120 are stacked the semiconductor package 1A may be a direction intersecting the Z-direction in which the through-hole 220h penetrates the core substrate 220, for example, the X-direction perpendicular to the Z-direction in a cross-section.

Each passive component module 100A may be electrically connected to the semiconductor chip 300 of the upper semiconductor package 20. For example, each passive component module 100A may be connected one-to-one to each semiconductor chip 300. In an embodiment, the plurality of passive component modules 100A may be connected to a single semiconductor chip 300. Alternatively, each passive component module 100A may be electrically connected to the plurality of semiconductor chips 300. In other words, the passive component module 100A may be dispersedly connected to the plurality of semiconductor chips 300.

The thickness T1 of the passive component module 100A may be substantially the same as or extremely similar to the thickness T2 of the core substrate 220. The thickness T1 of the passive component module 100A may be 1 mm or more. By forming the thickness T1 of the passive component module 100A to be the same as or similar to the thickness T2 of the core substrate 220, delamination and voids of the encapsulant 230 due to the thickness difference between them may be prevented, and accessibility of equipment used for arranging the passive component module 100A can be secured.

Referring to FIG. 6 and FIG. 7, each of the first electrode 122A and the second electrode 122B may be a power electrode or a ground electrode. The power electrode may be electrically connected to a power wire of the first redistribution structure 210 and the second redistribution structure 240, and the ground electrode may be electrically connected to a ground wire of the first redistribution structure 210 and the second redistribution structure 240, to perform the functions of stabilization, noise removal, or the like, of the power distribution network (PDN). When the first electrode 122A is a power electrode, it may be advantageous in the aspect of the wire design that the second electrode 122B spaced apart from (e.g., overlapping with) the first electrode 122A in the Z-direction is a ground electrode. When the first electrode 122A is a ground electrode, it may be advantageous in the aspect of the wire design that the second electrode 122B spaced apart from (e.g., overlapping with) the first electrode 122A in the Z-direction is a power electrode.

Referring to FIG. 8 and FIG. 9, the first electrode 122A and the second electrode 122B may be signal electrodes. The signal electrode may be electrically connected to a signal wire of the first redistribution structure 210 and the second redistribution structure 240, to provide the functions of maintaining signal integrity or the like. When the first electrode 122A is a signal electrode, it may be advantageous in the aspect of the wire design that the second electrode 122B spaced apart from (e.g., overlapping with) the first electrode 122A in the Z-direction is also a signal electrode.

The encapsulant 230 may fill at least a portion of the through-hole 220h and cover at least a portion of the passive component module 100A. The encapsulant 230 may extend onto an upper surface of the core substrate 220 and the passive component module 100A. The encapsulant 230 may be formed of an insulative material such as an epoxy molding compound (EMC). The encapsulant 230 may be formed by compression molding, transfer molding, or the like.

The second redistribution structure 240 may be disposed to extend on the core substrate 220 and the passive component module 100A and electrically connected to the core substrate 220 and the passive component module 100A. At least a portion of a space between the core substrate 220 and the passive component module 100A and the second redistribution structure 240 may be filled with the encapsulant 230, and accordingly, it may also be understood that the second redistribution structure 240 is disposed on the encapsulant 230.

The second redistribution structure 240 may be electrically connected to the core substrate 220 and/or the passive component module 100A by a connection vias 244 buried in the encapsulant 230. For example, the connection via 244 may electrically connect a second redistribution wiring layer 242 of the second redistribution structure 240 to the second wiring layer 222B of the core substrate 220 and/or the first electrode 122A of the passive component module 100A. A conductive material such as copper (Cu) or aluminum (Al) may be used as a material of the connection via 244. However, depending on the implementations, the second redistribution structure 240 may be directly connected to the core substrate 220 and/or the passive component module 100A.

The second redistribution structure 240 may include a second redistribution insulation layers 241, the second redistribution wiring layers 242 and a second redistribution vias 243.

The second redistribution insulation layer 241 may cover the second redistribution wiring layer 242, and may prevent an electrical short between the second redistribution wiring layers 242. An insulative material such as a photo-imageable dielectric (PID) may be used as a material of the second redistribution insulation layer 241. When a photo-imageable dielectric is used as a material of the second redistribution insulation layer 241, it may be advantageous for implementation of fine pitches. The second redistribution insulation layer 241 disposed uppermost among the second redistribution insulation layers 241 may serve as a passivation layer.

The second redistribution wiring layers 242 may be disposed on the second redistribution insulation layer 241, respectively. The second redistribution wiring layers 242 may include wires such as a signal wire for signal transmission, a power wire for supplying power, and a ground wire for grounding. A conductive material such as copper (Cu) or aluminum (Al) may be used as a material of the second redistribution wiring layer 242.

The second redistribution vias 243 may connect the second redistribution wiring layers 242 buried in the second redistribution insulation layer 241 and located in different layers. The same as the second redistribution wiring layer 242, a conductive material may be used as a material of the second redistribution via 243. The second redistribution via 243 may have various shapes such as a cylindrical shape or a tapered shape.

The upper semiconductor package 20 may include the interposer substrate 410, the semiconductor chips 300 and an encapsulant 420.

The interposer substrate 410 may be, for example, a silicon interposer substrate including a silicon substrate 411 and through vias 412 penetrating the silicon substrate 411. The interposer substrate 410 may serve as an intermediate substrate that electrically connects the semiconductor chips 300 disposed on the interposer substrate 410 and the component embedded substrate 10. In addition, the interposer substrate 410 may interconnect the semiconductor chips 300.

The type of each semiconductor chip 300 is not particularly limited, and may be a logic chip or memory chip. The logic chip may include at least one among an application processor (AP), a microprocessor, a central processing unit (CPU), a graphics processing unit (GPU), a neural processing unit (NPU), an application-specific integrated circuit (ASIC), and a system-on-chip (SoC). The memory chip may include at least one among a high-bandwidth memory (HBM) chip, a dynamic random-access memory (DRAM) chip, a static random-access memory (SRAM) chip, a flash memory chip, read-only memory (ROM) chip, and a magnetic random-access memory (MRAM) chip. The type of the semiconductor chips 300 may be the same as each other or may be different from each other.

Each semiconductor chip 300 may be mounted on the interposer substrate 410 through the conductive bumps 431. The conductive bumps 431 may be disposed between the semiconductor chip 300 and the interposer substrate 410, and may include a conductive material such as a solder. The size, shape, spacing, or the like of the conductive bumps 431 is not particularly limited, and may be changed depending on the implementations. The conductive bumps 431 may be covered by an underfill material 432 filling at least a portion of a space between the semiconductor chip 300 and the interposer substrate 410. The underfill material 432 may extend onto a side surface of a lower portion of the semiconductor chip 300. The underfill material 432 may include an epoxy resin, and may further include an inorganic filler of silica, alumina, or the like.

The encapsulant 420 may cover at least a portion of each of the semiconductor chips 300 on the interposer substrate 410. The encapsulant 420 may be formed of an insulative material such as an epoxy molding compound (EMC). The encapsulant 420 may be formed by compression molding, transfer molding, or the like. An upper surface of the semiconductor chips 300 may be exposed through an upper surface of the encapsulant 420. When the upper surface of the semiconductor chips 300 is exposed through the upper surface of the encapsulant 420, heat dissipation characteristics of the semiconductor package 1A may be improved.

The upper semiconductor package 20 may be mounted on the component embedded substrate 10 through the conductive bumps 531. The conductive bumps 531 may be disposed between the upper semiconductor package 20 and the component embedded substrate 10, and may include a conductive material such as a solder. The size, shape, spacing, or the like of the conductive bumps 531 is not particularly limited, and may be changed depending on the implementations. The conductive bumps 531 may be covered by an underfill material 532 filling at least a portion of a space between the upper semiconductor package 20 and the component embedded substrate 10. The underfill material 532 may extend onto a side surface of a lower portion of the upper semiconductor package 20 (e.g., a side surface of a lower portion of the interposer substrate 410). The underfill material 532 may include an epoxy resin, and may further include an inorganic filler of silica, alumina, or the like.

On the component embedded substrate 10, a semiconductor package including a single semiconductor chip 300 may be disposed, and semiconductor chip(s) in the form of bare chips that are not separately packaged may be disposed, of which the implementations are also considered to be included in the present disclosure.

Meanwhile, the case of introducing a core substrate having a thick thickness (e.g., 1 mm or more) for warpage control of the large-area package could be considered. In the case of an MLCC, product groups having a thickness of typically 300 μm or less may be manufactured, and in the case of a silicon capacitor, the available thickness of products that can be manufactured is limited due to the wafer thickness (approximately 780 μm). When a thickness of the passive component is thin than a thickness of the core substrate, problems of delamination, voids, or the like of the encapsulant may occur. Therefore, currently there are no capacitor product families suitable for being embedded in the core substrate of 1 mm or more. In addition, capacitors are typically used individually, and the capacitance may be determined by the physical characteristics of each capacitor, and the capacitor are generally connected only to the mounting surface side.

According one or more embodiments of to the present disclosure, by side-stacking the passive components 120, the passive component module 100A that can be embedded in the core substrate having a thick thickness without limitation caused by the wafer thickness may be provided. In addition, the passive component module 100A capable of securing high capacitance by stacking the plurality of passive components 120 may be provided. In addition, since vertical connection to the mounting surface may be enabled through the first electrode 122A and the second electrode 122B located on the opposite surface, respectively, the passive component module 100A having characteristics advantageous for a power distribution network (PDN) may be provided.

For configurations other than the above, the content described in detail in other portions of the present disclosure may be equally applied, unless particularly contradictory.

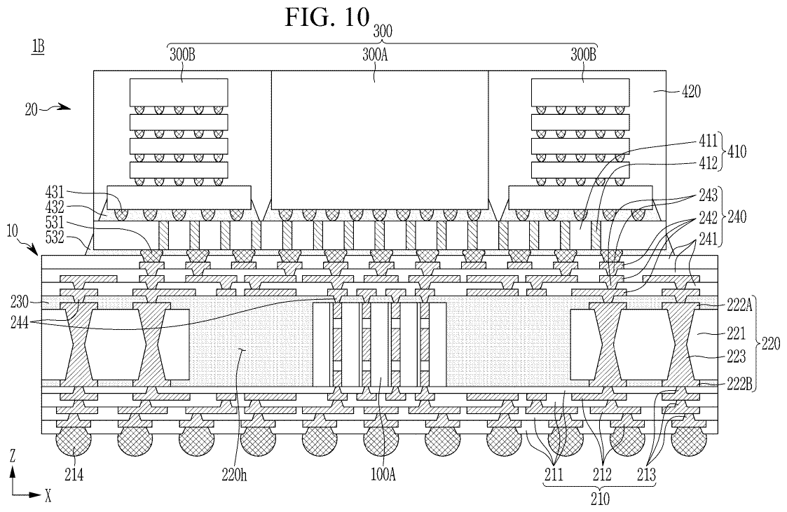

FIG. 10 is a cross-sectional view of the semiconductor package according to an embodiment.

A semiconductor package 1B according to an embodiment exemplifies another type of 2.5D semiconductor package to which the passive component module 100A is applied.

The semiconductor chips 300 of the semiconductor package 1B may include a first semiconductor chip 300A and second semiconductor chips 300B of different types. The first semiconductor chip 300A may be a logic chip such as a system-on-chip (SoC), and the second semiconductor chips 300B may be a memory chip such as a high-bandwidth memory (HBM) chip in a structure in which a plurality of chips are stacked. The passive component module 100A may be connected, for example, to a logic chip having high power consumption, thereby improving impedance characteristics and performance.

For configurations other than the above, the content described in detail in other portions of the present disclosure may be equally applied, unless particularly contradictory.

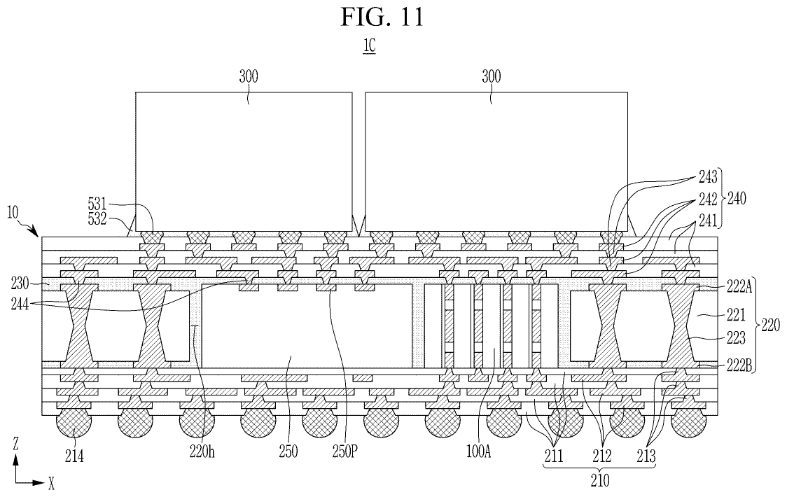

FIG. 11 is a cross-sectional view of the semiconductor package according to still an embodiment.

The passive component module 100A may be applied to the large-area 2.3D semiconductor package including a bridge chip 250 providing electrical connection between the semiconductor chips 300.

A semiconductor package 1C according to an embodiment may include the component embedded substrate 10 and the semiconductor chips 300 disposed on the component embedded substrate 10.

In addition, the component embedded substrate 10 of the semiconductor package 1C according to an embodiment may further include the bridge chip 250 disposed on the first redistribution structure 210 so that at least a portion may be located within the through-hole 220h.

The bridge chip 250 may include a connection pad 250P, and may be disposed on the first redistribution structure 210 in the face-up form so that the surface on which the connection pad 250P is disposed may face the second redistribution structure 240. The adhesive member (e.g., die attach film (DAF)) may be interposed between the bridge chip 250 and the first redistribution structure 210. However, the bridge chip 250 may be disposed on the first redistribution structure 210 in the face-down form so that the surface on which the connection pad 250P is disposed may face first redistribution structure 210.

In an embodiment, the bridge chip 250 may be disposed adjacent to (side by side with) the passive component module 100A within the through-hole that is the same as the through-hole 220h in which the passive component module 100A is disposed. The bridge chip 250 may electrically connect the plurality of semiconductor chips 300 disposed on the component embedded substrate 10. The bridge chip 250 may be spaced apart from the passive component module 100A and the core substrate 220, and at least a portion of each of a space between the bridge chip 250 and the passive component module 100A and a space between the bridge chip 250 and the core substrate 220 may be filled with the encapsulant 230.

For configurations other than the above, the content described in detail in other portions of the present disclosure may be equally applied, unless particularly contradictory.

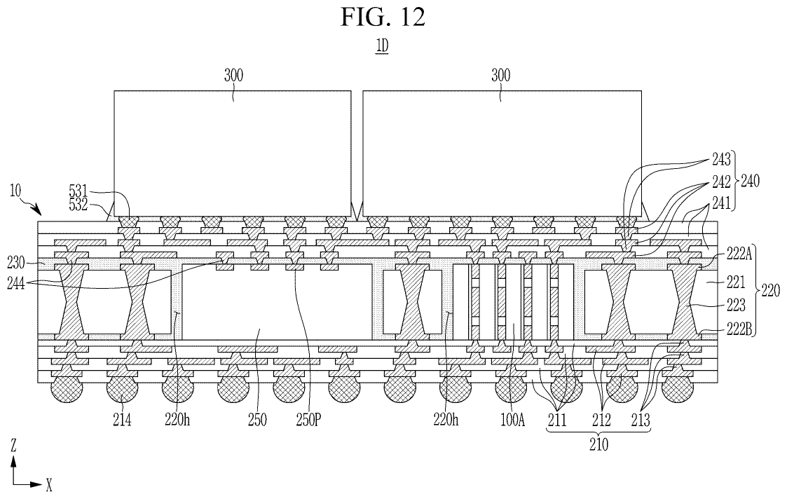

FIG. 12 is a cross-sectional view of the semiconductor package according to still an embodiment.

In comparison with the case of the semiconductor package 1C, the bridge chip 250 of a semiconductor package 1D may be disposed within a still another through-hole 220h distinguished from the through-hole 220h in which the passive component module 100A is disposed.

For configurations other than the above, the content described in detail in other portions of the present disclosure may be equally applied, unless particularly contradictory.

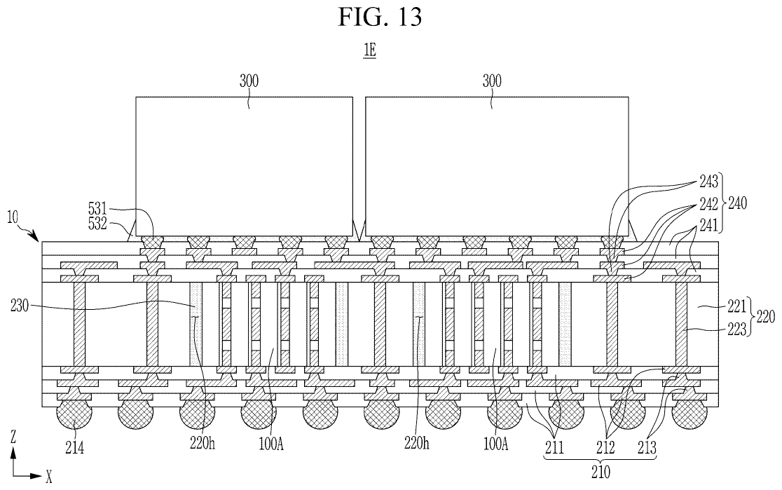

FIG. 13 is a cross-sectional view of the semiconductor package according to still an embodiment.

The passive component module 100A may be introduced into the semiconductor package including the interposer substrate providing electrical connection between the semiconductor chips 300.

A semiconductor package 1E according to an embodiment may include the component embedded substrate 10 functioning as the interposer substrate and the semiconductor chips 300 disposed on the component embedded substrate 10.

The component embedded substrate 10 in which the passive component module 100A is embedded may be, for example, a silicon interposer substrate that utilizes the silicon substrate as the core insulation layer 221 and in which the through via 223 is formed. The component embedded substrate 10 may be manufactured, for example, by forming the through-hole 220h in the core insulation layer 221, and disposing the passive component module 100A in the through-hole 220h, filling a remaining portion of the through-hole 220h with the encapsulant 230, and then forming the through via 223, the first redistribution structure 210, and the second redistribution structure 240. Depending on embodiments, the through via 223 may be formed in advance before forming the through-hole 220h of the core insulation layer 221. The passive component module 100A may contact the first redistribution structure 210 and the second redistribution structure 240, but is not limited thereto.

For configurations other than the above, the content described in detail in other portions of the present disclosure may be equally applied, unless particularly contradictory.

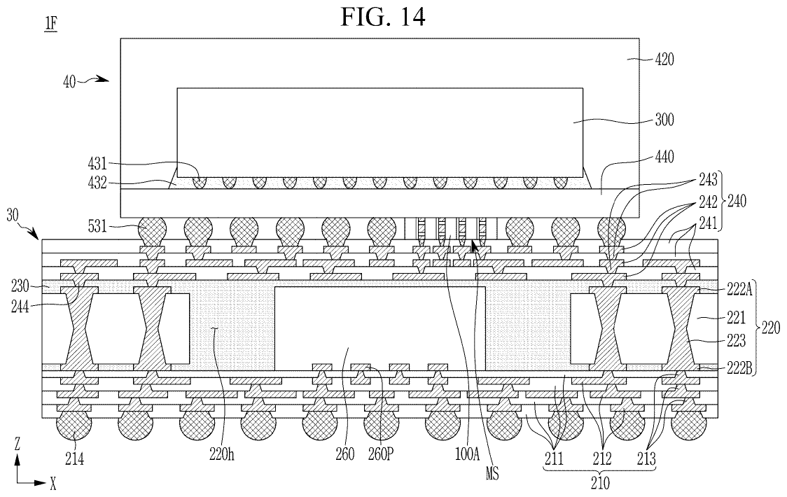

FIG. 14 is a cross-sectional view of the semiconductor package according to still an embodiment.

The passive component module 100A may be applied to the semiconductor package of a package-on-package (POP) type.

A semiconductor package 1F according to an embodiment may include a first semiconductor package 30, a second semiconductor package 40 disposed on the first semiconductor package 30, a plurality of conductive bumps 531 disposed between the first semiconductor package 30 and the second semiconductor package 40, and the passive component module 100A disposed adjacent to (side by side) with the plurality of conductive bumps 531 between the first semiconductor package 30 and the second semiconductor package 40.

The first semiconductor package 30 may include the first redistribution structure 210, the core substrate 220 disposed on the first redistribution structure 210 and having the through-hole 220h, a semiconductor chip 260 disposed on the first redistribution structure 210 so that at least a portion may be located within the through-hole 220h, the encapsulant 230 filling at least a portion of the through-hole 220h and covering at least a portion of the semiconductor chip 260, and the second redistribution structure 240 disposed to extend on the core substrate 220 and the semiconductor chip 260.

The second semiconductor package 40 may include a substrate 440, at least a portion of the semiconductor chip 300 disposed on the substrate 440 and the encapsulant 420 covering the semiconductor chip 300. The substrate 440 may be a printed circuit board (PCB).

The conductive bumps 531 may be disposed between the first semiconductor package 30 and the second semiconductor package 40, and may include a conductive material such as a solder. The size, shape, spacing, or the like of the conductive bumps 531 is not particularly limited, and may be changed depending on the implementations.

The passive component module 100A may be disposed side by side with the plurality of conductive bumps 531 between the first semiconductor package 30 and the second semiconductor package 40. The passive component module 100A may be disposed on the first semiconductor package 3 (in the same direction as illustrated in FIG. 1) so that the surface on which the second electrode 122B is disposed may become the mounting surface MS. Therefore, the direction in which the plurality of passive components 120 are stacked the semiconductor package 1F may be a direction intersecting the Z-direction from the first semiconductor package 30 toward the second semiconductor package 40, for example, the X-direction perpendicular to the Z-direction in a cross-section.

The passive component module 100A may be electrically connected to the first semiconductor package 30 and the second semiconductor package 40. For example, the first electrode 122A of the passive component module 100A may be connected to the substrate 440 of the second semiconductor package 40, and the second electrode 122B may be connected to the second redistribution structure 240 of the first semiconductor package 30. Each of the first electrode 122A and the second electrode 122B of the passive component module 100A disposed side by side with the conductive bumps 531 may include a solder. In addition, the first electrode 122A and the second electrode 122B may be coupled to the first semiconductor package 30 and the second semiconductor package 40 through a conductive member such as a solder paste.

FIGS. 15 to 18 are manufacturing process diagrams of the passive component module according to an embodiment.

The passive component module 100A according to an embodiment may be manufactured by stacking the plurality of passive components 120 on the support substrate 110. For example, the passive component module 100A may be manufactured by attaching the first passive component 120A on the support substrate 110 through the adhesive member 130, and sequentially stacking the second passive component 120B, the third passive component 120C and the fourth passive component 120D on the first passive component 120A.

The dummy electrode 123 for preventing a crack due to the stack of the passive components 120 with a thin thickness may be formed in each passive component 120.

The passive components 120 may be stacked through the adhesive member 130 such as a non-conductive adhesive film. The support substrate 110 and the passive components 120 may be bonded to each other in the wafer-on-wafer (WoW) method in the wafer state. However, the passive components 120 of the chip state may be bonded on the support substrate 110 of the wafer state by the chip-on-wafer (CoW) method, and the support substrate 110 and the passive components 120 may be bonded by the chip-on-chip (CoC) method in individual chip states.

According to the present disclosure, by adjusting the lengths of the support substrate 110 and the passive components 120 along the X-direction and the Y-direction when manufacturing the passive component module 100A manufacture, the passive component module 100A having a thick thickness without limitation caused by the wafer thickness may be manufactured. In addition, by adjusting the number of the stacked passive components 120, the capacitance of the passive component module 100A may be adjusted.

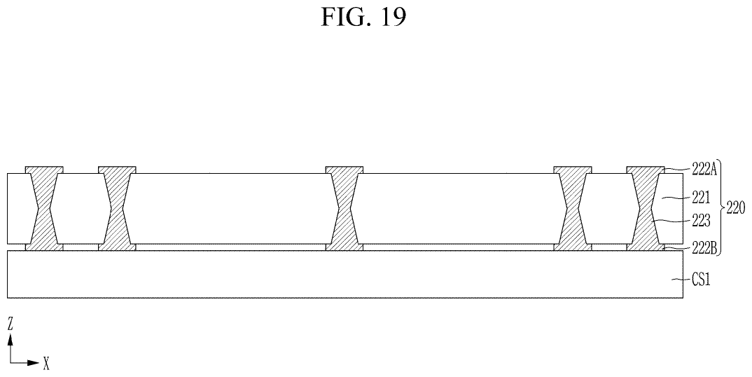

FIG. 19 to 29 are manufacturing process diagrams of the semiconductor package according to an embodiment.

The semiconductor package according to an embodiment may be manufactured by manufacturing the component embedded substrate 10 including the passive component module 100A, and disposing the upper semiconductor package 20 on the component embedded substrate 10.

In an embodiment, a manufacturing method of the component embedded substrate 10 may include disposing the passive component module 100A within the through-hole 220h of the core substrate 220, forming the encapsulant 230 filling at least a portion of the through-hole 220h and covering at least a portion of the passive component module 100A, forming the second redistribution structure 240 on a first surface of the core substrate 220, and forming the first redistribution structure 210 on a second surface of the core substrate 220.

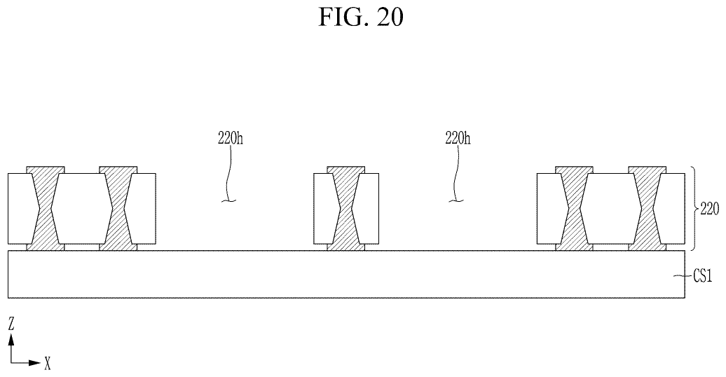

First, referring to FIGS. 19 and 20, the core substrate 220 may be disposed on a first carrier structure CS1, and the through-hole 220h may be formed in the core substrate 220. The number of the through-holes 220h is not particularly limited, and may be changed according to the number of the passive component module 100A or the like. The formation method of the through-hole 220h is not particularly limited, and may be formed by a laser processing, a mechanical processing, or the like. Depending on the processing method, a width of the through-hole 220h on the cross-section may be constant, or may be narrowed in a direction from a first side toward a second side.

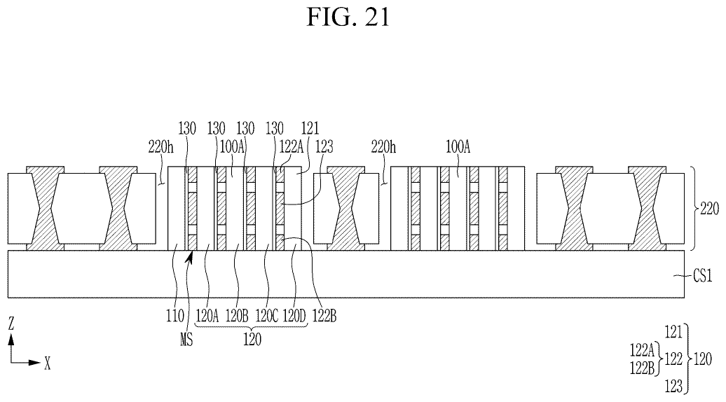

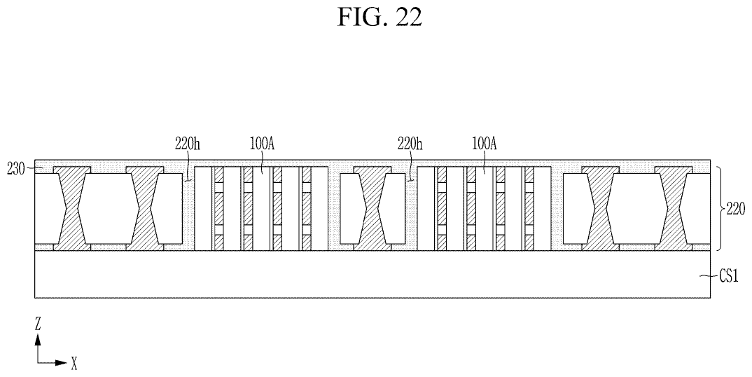

Subsequently, referring to FIGS. 21 and 22, the passive component module 100A may be dispose within each through-hole 220h, and the encapsulant 230 filling at least a portion of the through-hole 220h and covering at least a portion of the passive component module 100A may be formed. The passive component module 100A may be disposed so that the mounting surface MS on which the second electrode 122B is disposed may face the first carrier structure CS1. The encapsulant 230 may be formed to extend onto an upper surface of each of the core substrate 220 and the passive component module 100A.

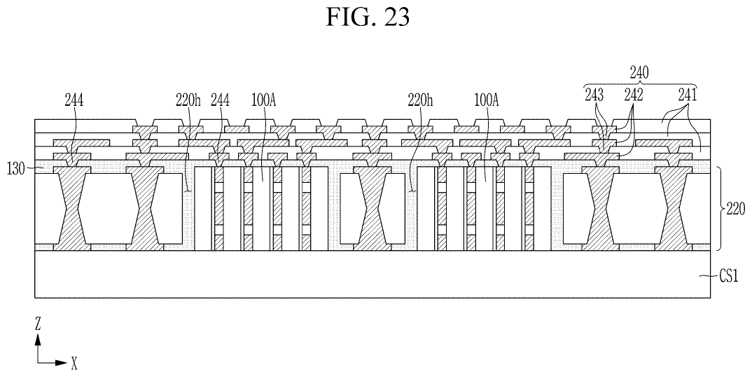

Subsequently, referring to FIG. 23, the second redistribution structure 240 may be formed on the encapsulant 230. The second redistribution structure 240 may be manufactured by sequentially forming the second redistribution wiring layer 242, the second redistribution insulation layer 241, and the second redistribution via 243 on the encapsulant 230, repeatedly if necessary.

If necessary, the connection via 244 buried in the encapsulant 230 before forming the second redistribution structure 240 and connected to the core substrate 220 and the passive component module 100A may be formed. The connection via 244 may be formed, for example, removing a part of the encapsulant 230 in the Z-direction to expose the second wiring layer 222B of the core substrate 220 and the first electrode 122A of the passive component module 100A, and filling the removed region of the encapsulant 230 with a conductive material. The second redistribution structure 240 may be formed to be electrically connected to the connection via 244.

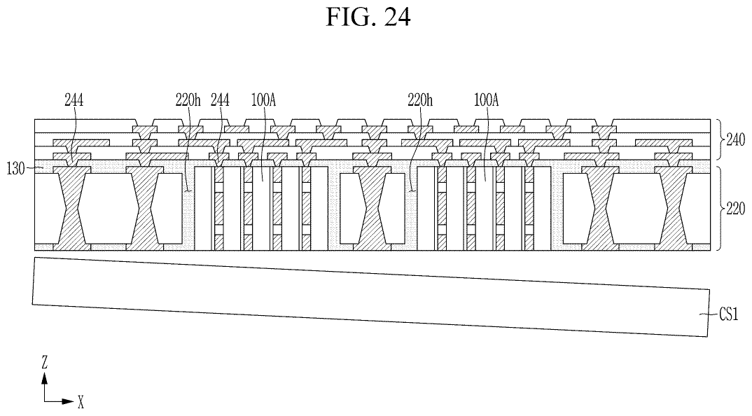

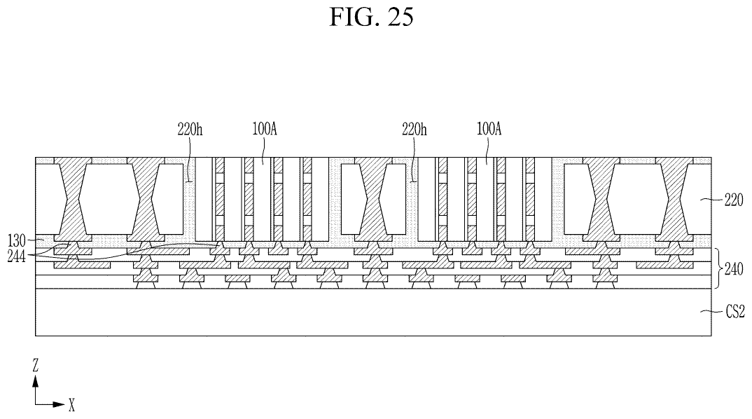

Subsequently, referring to FIGS. 24 and 25, the first carrier structure CS1 may be removed, and a second carrier structure CS2 may be attached to the second redistribution structure 240. The removal method of the first carrier structure CS1 is not particularly limited, and it may be removed by heat treatment, ultraviolet ray processing, or the like.

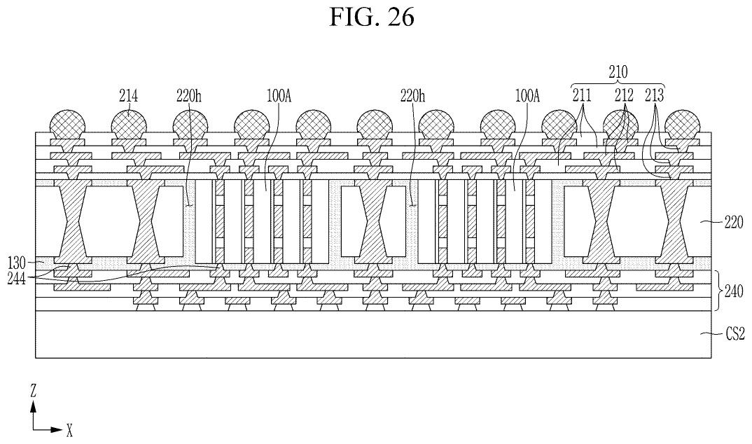

Subsequently, referring to FIG. 26, the first redistribution structure 210 may be formed an opposite surface (the surface on which the first carrier structure CS1 is removed) of the surface on which the second redistribution structure 240 of the core substrate 220 is formed. The first redistribution structure 210 may also be manufactured by sequentially forming the first redistribution wiring layer 212, the first redistribution insulation layer 211, and the first redistribution via 213, repeatedly if necessary. If necessary, the conductive bump 214 may be formed on the first redistribution structure 210.

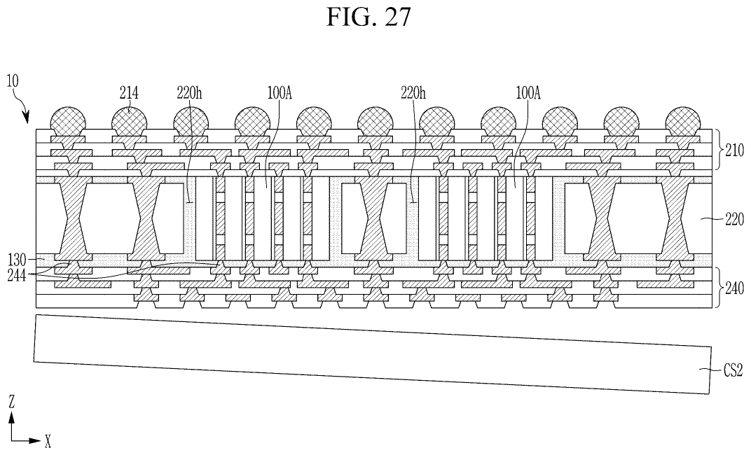

Subsequently, referring to FIG. 27, the component embedded substrate 10 may be manufactured by removing the second carrier structure CS2. The removal method of the second carrier structure CS2 is not particularly limited, and it may be removed by heat treatment, ultraviolet ray processing, or the like.

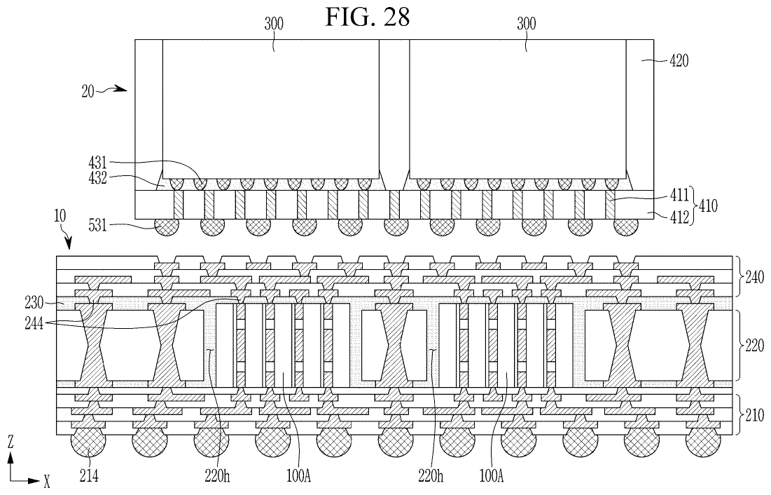

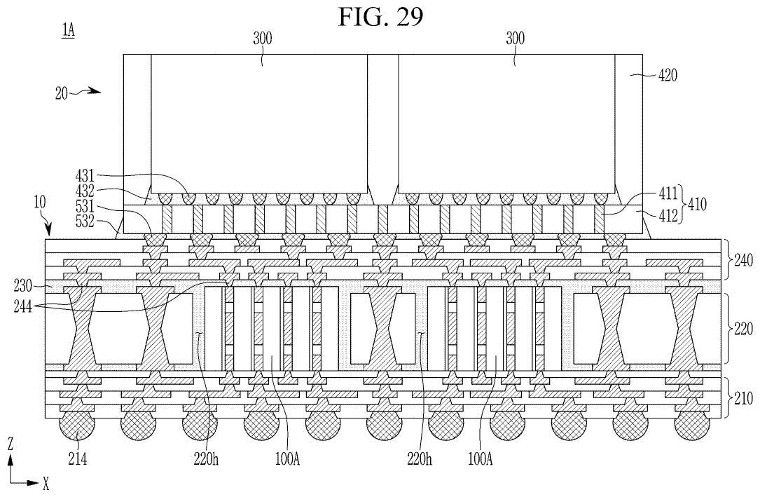

Finally, referring to FIGS. 28 and 29, by disposing the upper semiconductor package 20 on the manufactured component embedded substrate 10, the semiconductor package 1A according to an embodiment may be provided. The upper semiconductor package 20 may be mounted on the component embedded substrate 10 through the conductive bump 531, and if necessary, the underfill material 532 covering the conductive bump 531 may be additionally formed.

For configurations other than the above, the content described in detail in other portions of the present disclosure may be equally applied, unless particularly contradictory.

While certain example embodiments of disclosure have been described and shown, it is to be understood that the disclosure is not limited to the disclosed embodiments, but, on the contrary, is intended to cover various modifications and equivalent arrangements included within the spirit and scope of the appended claims.

Additionally, the example embodiments of the present disclosure are not independent from each other and may be implemented in combination with each other unless there is a particular conflict. Accordingly, embodiments in which embodiments of the present disclosure are combined should also be considered to be included in the scope of the present disclosure.

What is claimed is:

1. A passive component module comprising:
a support substrate;
a plurality of passive components stacked on the support substrate in a first direction, each of the plurality of passive components comprising:
a body having a first surface and a second surface facing the first surface in the first direction,
a first electrode on the first surface of the body, and
a second electrode on the first surface of the body and spaced apart from the first electrode; and
a plurality of adhesive members between the support substrate and the plurality of passive components and between the plurality of passive components.

2. The passive component module of claim 1, wherein each of the plurality of passive components further comprises a dummy electrode on the first surface of the body and spaced apart from each of the first electrode and the second electrode.

3. The passive component module of claim 1, further comprising a filling member filling at least a portion of an area between the first electrode and the second electrode of each of the plurality of passive components.

4. The passive component module of claim 1, wherein the first surface of the body of each of the plurality of passive components faces the support substrate.

5. The passive component module of claim 1, wherein each of the plurality of passive components is a silicon capacitor.

6. The passive component module of claim 1, wherein the support substrate is a dummy wafer.

7. The passive component module of claim 1, wherein each of the plurality of adhesive members is a non-conductive adhesive film.

8. The passive component module of claim 1, wherein a length of the passive component module in a direction from the second electrode toward the first electrode is at least 1 mm.

9. The passive component module of claim 1, wherein the second electrode of each of the plurality of passive components is disposed on a mounting surface of the passive component module; and
wherein the first electrode of each of the plurality of passive components is on a surface of the passive component module opposite to the mounting surface.

10. A semiconductor package comprising:
a component embedded substrate; and
at least one semiconductor chip on the component embedded substrate and electrically connected to the component embedded substrate,
wherein the component embedded substrate comprises:
a first redistribution structure;
a core substrate on the first redistribution structure and electrically connected to the first redistribution structure, the core substrate having a first through-hole therein;
a passive component module on the first redistribution structure, at least a portion of the passive component module being within the first through-hole and electrically connected to the first redistribution structure, the passive component module comprising a plurality of passive components arranged along a first direction;
an encapsulant filling at least a portion of the first through-hole, and covering at least a portion of the passive component module; and
a second redistribution structure extending on the core substrate and the passive component module, and electrically connected to the core substrate and the passive component module,
wherein the first direction intersects a second direction in which the first through-hole penetrates the core substrate, and
wherein each of the plurality of passive components comprises:
a first electrode connected to the second redistribution structure; and
a second electrode spaced apart from the first electrode in the second direction and connected to the first redistribution structure.

11. The semiconductor package of claim 10, wherein the first electrode is a power electrode, and
wherein the second electrode is a ground electrode.

12. The semiconductor package of claim 10, wherein each of the first electrode and the second electrode is a signal electrode.

13. The semiconductor package of claim 10, wherein the at least one semiconductor chip comprises a plurality of semiconductor chips, and
wherein the passive component module is electrically connected to each of the plurality of semiconductor chips.

14. The semiconductor package of claim 10, wherein a length of the core substrate in the second direction is at least 1 mm.

15. The semiconductor package of claim 10, wherein a length of the passive component module in the second direction is at least 1 mm.

16. The semiconductor package of claim 10, wherein the at least one semiconductor chip comprises a plurality of semiconductor chips,
wherein the component embedded substrate further comprises a bridge chip adjacent to the passive component module on the first redistribution structure, and electrically connecting the plurality of semiconductor chips, and
wherein at least a portion of the bridge chip is within the first through-hole of the core substrate, and.

17. The semiconductor package of claim 10, wherein the at least one semiconductor chip comprises a plurality of semiconductor chips,
wherein the core substrate further has a second through-hole therein,
wherein the component embedded substrate further comprises a bridge chip on the first redistribution structure, and electrically connecting the plurality of semiconductor chips, and
wherein at least a portion of the bridge chip is within the second through-hole of the core substrate.

18. The semiconductor package of claim 10, wherein the core substrate comprises:
a core insulation layer;
a first wiring layer on a first surface of the core insulation layer;
a second wiring layer on a second surface of the core insulation layer opposite to the first surface; and
a through via penetrating the core insulation layer and electrically connecting the first wiring layer and the second wiring layer.

19. A semiconductor package comprising:
a first semiconductor package;
a second semiconductor package on the first semiconductor package;
a plurality of conductive bumps between the first semiconductor package and the second semiconductor package; and
a passive component module adjacent to the plurality of conductive bumps between the first semiconductor package and the second semiconductor package, the passive component module comprising a plurality of passive components arranged along a first direction,
wherein the first direction intersects a second direction from the first semiconductor package toward the second semiconductor package, and
wherein each of the plurality of passive components comprises:
a first electrode connected to the second semiconductor package; and
a second electrode spaced apart from the first electrode in the second direction and connected to the first semiconductor package.

20. The semiconductor package of claim 19, wherein each of the first electrode and the second electrode comprises solder.
